(19) United States
(12) Patent Application Publication
(10) Pub. No.: US 2026/0118443 A1
(43) Pub. Date: Apr. 30, 2026

(54) OPERATION MANAGEMENT SUPPORT METHOD AND OPERATION MANAGEMENT SUPPORT APPARATUS

(71) Applicant: Panasonic Intellectual Property Management Co., Ltd., Osaka (JP)

(72) Inventor: So KAIHATSU, Chiba Ken (JP)

(73) Assignee: Panasonic Intellectual Property Management Co., Ltd., Osaka (JP)

(21) Appl. No.: 19/427,358

(22) Filed: Dec. 19, 2025

Related U.S. Application Data
(63) Continuation of application No. PCT/JP2024/001860, filed on Jan. 23, 2024.

(30) Foreign Application Priority Data
Aug. 10, 2023 (JP) 2023-130768

(51) Int. Cl. G01R 31/392; B60L 58/10; G01R 31/367

(52) U.S. Cl. CPC G01R 31/392; B60L 58/10; G01R 31/367

(57) ABSTRACT

An operation management support method according to the present disclosure includes: acquiring first battery information about a storage battery mounted on at least one vehicle of a first vehicle type as a management target and second battery information about storage batteries of a vehicle type group including at least the first vehicle type; comparing the first battery information with the second battery information to perform analyzation of storage battery performance of the first vehicle type; and outputting display information for displaying a result of evaluation of the storage battery performance of the first vehicle type based on the analysis.

### CROSS-REFERENCE TO RELATED APPLICATIONS

This application is a continuation of International Application No. PCT/JP2024/001860, filed on January 23, 2024 which claims the benefit of priority of the prior Japanese Patent Application No. 2023-130768, filed on August 10, 2023, the entire contents of which are incorporated herein by reference.

### FIELD

The present disclosure relates to an operation management support method and an operation management support apparatus.

### BACKGROUND

Conventionally, companies such as transport companies, logistics companies, and rental car companies have conducted operation management business for management of owned or leased electrically driven vehicles capable of traveling using electric power from mounted storage batteries, such as electric vehicles and hybrid vehicles.

In operation management of the electrically driven vehicles, storage battery performance, such as the deterioration degree and quality of the mounted storage batteries, is regarded as important. For example, there is disclosed a technique to compare the deterioration degree of a secondary battery of an owned host vehicle with a battery of the same type or a battery of the same type mounted on a vehicle of the same type, for objective understanding of a battery use status and display of an appropriate battery use method according to the battery use status (e.g., see JP 7015395 B2).

Under such circumstances, considering, for example, use as evaluation criteria for additional introduction such as additional purchase or additional rental of the electrically driven vehicles by the companies that manage the operation of the electrically driven vehicles, evaluation information for evaluating the storage battery performance is preferably information according to an operation form of each of the companies. Therefore, there is room for improvement of storage battery performance evaluation information that is to be presented to the company that conducts the operation management business for the electrically driven vehicles.

### SUMMARY

An operation management support method according to the present disclosure includes: acquiring first battery information about a storage battery mounted on at least one vehicle of a first vehicle type as a management target and second battery information about storage batteries of a vehicle type group including at least the first vehicle type; comparing the first battery information with the second battery information to perform analyzation of storage battery performance of the first vehicle type; and outputting display information for displaying a result of evaluation of the storage battery performance of the first vehicle type based on the analysis.

### BRIEF DESCRIPTION OF THE DRAWINGS

FIG. 1 is a diagram illustrating an exemplary configuration of a support system according to an embodiment;

FIG. 2 is a diagram illustrating an exemplary hardware configuration of devices of the support system according to an embodiment;

FIG. 3 is a diagram illustrating an exemplary functional configuration of a management device according to an embodiment;

FIG. 4 is a diagram illustrating an exemplary functional configuration of a server according to an embodiment;

FIG. 5 is a flowchart illustrating an exemplary procedure of a support process performed by the management device according to an embodiment;

FIG. 6 is a diagram illustrating an example of a display screen displayed in the process of FIG. 5; and

FIG. 7 is a view illustrating an example of a display screen displayed in the process of FIG. 5.

### DETAILED DESCRIPTION

Hereinafter, embodiments of an operation management support method, an operation management support apparatus, a support system, a program, and a storage medium according to the present disclosure will be described with reference to the drawings.

Note that in the description of the present disclosure, component elements having the same or substantially the same functions as those having been described with reference to previous drawings are denoted by the same reference numerals, and the description thereof is appropriately omitted, in some cases. In addition, even when the same or substantially the same portions are illustrated, the dimensions and ratios may be represented differently from each other depending on drawings. Furthermore, for example, from the viewpoint of ensuring visibility of the drawings, only main component elements are denoted by reference numerals in description of the drawings, and even if component elements having the same or substantially the same functions as those having illustrated in previous drawings are illustrated, the component elements may not be denoted by reference numerals.

Conventionally, a company such as a transport company, a logistics company, or a rental car company has conducted operation management business for management of an owned or leased electrically driven vehicle capable of traveling using electric power from a mounted storage battery, such as an electric vehicle or hybrid vehicle.

In general storage batteries, deterioration occurs that is, for example, decrease in maximum capacity caused by various factors use conditions such as an input/output current value, charge and discharge cycles, or a travel distance of an electrically driven vehicle on which the storage battery is mounted, a use environment such as an ambient temperature in charging and discharging, or an elapsed years from manufacturing. In addition, the general storage batteries may have a variation in quality depending on, for example, a manufacturing date, a manufacturing place, or a manufacturer. For these reasons, in operation management of the electrically driven vehicle, storage battery performance such as the deterioration degree and quality of mounted storage batteries is regarded as important.

For example, there has been a technique to compare the deterioration degree of a secondary battery of an owned host vehicle with a battery of the same type or a battery of the same type mounted on a vehicle of the same type, for objective understanding of a battery use status and display of an appropriate battery use method according to the battery use status. In the above technique, for improvement of driving by a driver by him/her-self, storage battery performance information in each of electrically driven vehicles, owned as an owner car, has been provided for the driver.

Under such circumstances, in some cases, a plurality of electrically driven vehicles of a plurality of vehicle types, such as held fleet cars is managed by the company such as the transport company, the logistics company, or the rental car company. Therefore, considering, for example, use of the evaluation information as evaluation criteria for additional introduction such as additional purchase or additional rental of the electrically driven vehicles by the companies that manage the operation of the electrically driven vehicles, the performance information indicating the storage battery performance is preferably information according to an operation form of each of the companies.

However, according to the comparison between batteries of the same type or batteries of the same type mounted on vehicles of the same type, there is a problem that information based on comparison of the storage battery performance in a vehicle type group including, for example, a plurality of vehicle types cannot be provided as the performance information indicating the storage battery performance. In addition, there is a problem that a form in which a vehicle side provides the performance information indicating the storage battery performance is unsuitable for a request in the operation management business, such as wanting to compare the storage battery performance in the vehicle type group. In this way, there is room for improvement in the storage battery performance information that is to be presented to the companies that conduct the operation management business for the electrically driven vehicles and the form of providing it.

Therefore, an object of the present disclosure is to provide storage battery performance information that supports operation management business for management of electrically driven vehicles with storage batteries mounted. For example, an object of at least one embodiment of the present disclosure is to provide storage battery performance information that serves as evaluation criteria for additional introduction of an electrically driven vehicle by the company that manages the plurality of vehicles of the plurality of vehicle types, such as the transport company, the logistics company, or the rental car company. For example, an object of at least one embodiment of the present disclosure is to provide information according to an operation form for each company as the storage battery performance information. For example, an object of at least one embodiment of the present disclosure is to provide a user interface system that allows the company that owns electrically driven vehicles with storage batteries mounted to readily grasp a vehicle type having good storage battery performance.

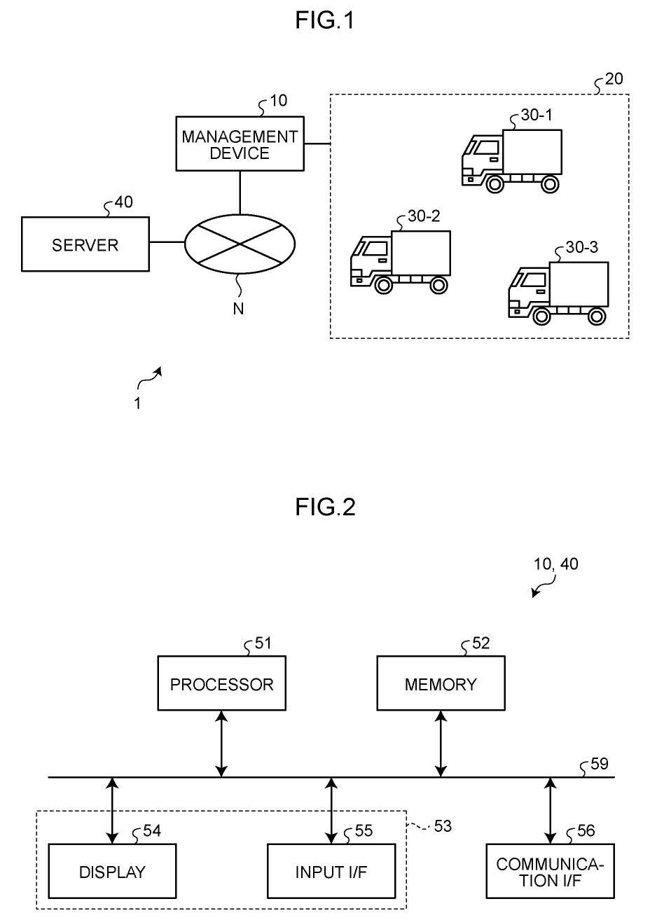

FIG. 1 is a diagram illustrating an exemplary configuration of a support system 1 according to an embodiment. As illustrated in FIG. 1, the support system 1 includes a management device 10, a fleet 20, and a server 40. The management device 10 and the server 40 are communicably connected via, for example, a network N. For the network N, for example, a telecommunication line such as the Internet can be used.

The support system 1 is configured to provide a support service that supports the operation management business of managing the fleet 20 including a plurality of electrically driven vehicles of a plurality of vehicle types, for the company that uses the support system 1, such as the transport company, the logistics company, or the rental car company. The support service provides the storage battery performance information for supporting the operation management business, for the company that uses the support service.

In an example, the support system 1 can be established as a server-client type system that includes the server 40, and the management device 10 as a client device. For the management device 10, various computers such as a smartphone, a personal computer (PC), a tablet PC, and a car navigation system can be appropriately used. For the server 40, various computers such as a server device and a PC can be appropriately used.

The management device 10 is a device that is operated by, for example, the company that uses the support service by the support system 1 and that supports the operation management business of the company. The management device 10 is configured to enable performance of a support process performed in the client according to the embodiment. Here, the management device 10 according to the embodiment is an example of the operation management support apparatus.

The fleet 20 includes a plurality of vehicles 30 of a plurality of vehicle types that is owned or leased and managed by the company using the support system 1. The plurality of vehicles 30 includes, for example, various electrically driven vehicles that use storage batteries, such as electric vehicles and hybrid vehicles. The storage batteries are each a secondary battery that stores power supplied from outside, such as commercial power, or regenerative electric power and discharges power for traveling drive of each of the vehicles 30.

Note that for the storage battery, various secondary batteries such as a lead storage battery, a lithium ion battery, a nickel-hydrogen battery, a nickel-cadmium battery, and an all-solid-state battery can be appropriately used. In addition, the vehicle 30 is preferably an electrically driven vehicle driven by using power from a mounted storage battery, and a bicycle, a motorcycle, another automobile such as a passenger car with three or more wheels or a truck, a scooter, or the like can be appropriately used.

Note that in FIG. 1, a first vehicle 30-1 of a first vehicle type, a second vehicle 30-2 of a second vehicle type, and a third vehicle 30-3 of a third vehicle type are illustrated, but the vehicles are not limited thereto. In the present disclosure, the fleet 20 may include one or two vehicle type groups, or may include a plurality of four or more vehicle type groups. Furthermore, each of the vehicle type groups may include any number of vehicles 30, and may include one vehicle or a plurality of two or more vehicles.

The server 40 is a device that is operated by a company providing the support service by the support system 1 and that supports the operation management business of the company that uses the support service. The server 40 is configured to enable performance of a support process performed in the server according to the embodiment.

Note that in the support system 1 according to the present disclosure, some of the functions of the management device 10 may be implemented by the server 40. At this time, the management device 10 may be configured as a device that receives an input of battery information about a storage battery, an operation to designate an analysis target, a display content changing operation, and the like by the company, and that displays at least one display screen showing the storage battery performance information, on a web browser or an application.

FIG. 2 is a diagram illustrating an exemplary hardware configuration of devices (e.g., the management device 10 and the server 40) of the support system 1 according to an embodiment.

As illustrated in FIG. 2, each of the devices of the support system 1 includes a processor 51, a memory 52, HMI 53, and a communication interface (I/F) 56. The HMI 53 includes a display 54 and an input I/F 55. The processor 51, the memory 52, the display 54, the input I/F 55, and the communication I/F 56 are mutually connected by a bus 59 or the like, and have a hardware configuration using a usual computer.

The processor 51 is an arithmetic device that entirely controls each device of the support system 1. For example, the processor 51 loads a program stored in a read only memory (ROM) or the like of the memory 52, into a random access memory (RAM), for execution, thereby implementing processes described later.

Note that, for the processor 51 according to the embodiment, various processors such as a central processing unit (CPU), a graphics processing unit (GPU), and a digital signal processor (DSP), a dedicated arithmetic circuit implemented by an application specific integrated circuit (ASIC) and a field programmable gate array (FPGA), and the like can be appropriately used.

The memory 52 stores programs, parameters, and the like that implement various processes by the processor 51. For example, the memory 52 is a main storage device of each device of the support system 1, and includes RAM that temporarily stores data necessary for various processes by the processor 51. For example, the memory 52 includes various storage media and storage devices such as ROM, a hard disk drive (HDD), a solid state drive (SSD), and a flash memory that store various data, programs, and the like used for each device of the support system 1.

The display 54 is an example of an output I/F of the HMI 53. The display 54 is configured to be able to output an image and a video. The display 54 is, for example, a liquid crystal display (LCD) or an organic electro luminescence (EL) display. Note that the display 54 may be configured as a touch screen display. Here, the display 54 of the management device 10 according to the embodiment is an example of a display unit.

The input I/F 55 is implemented as, for example, a touch screen of the display 54 as the touch panel display. Note that the input I/F 55 may include another input I/F such as a keyboard, a mouse, a button, a dial, a switch, or a microphone. Here, the input I/F 55 of the management device 10 according to the embodiment is an example of an acquisition unit.

Note that, for the HMI 53, an operation terminal capable of transmitting or transmitting/receiving a signal from outside each device, such as a tablet terminal, a smartphone, a smartwatch, or a remote controller may be used.

Note that the server 40 may not be provided with the HMI 53.

The communication I/F 56 is an interface for transmitting and receiving data. For example, for the communication I/F 56, a communication circuit for wired communication, a communication circuit for wireless communication, and a combination thereof can be appropriately used. For the communication circuit for wireless communication, a communication circuit supporting various standards such as 3G, 4G, Wi-Fi (registered trademark), and Bluetooth (registered trademark) can be appropriately used.

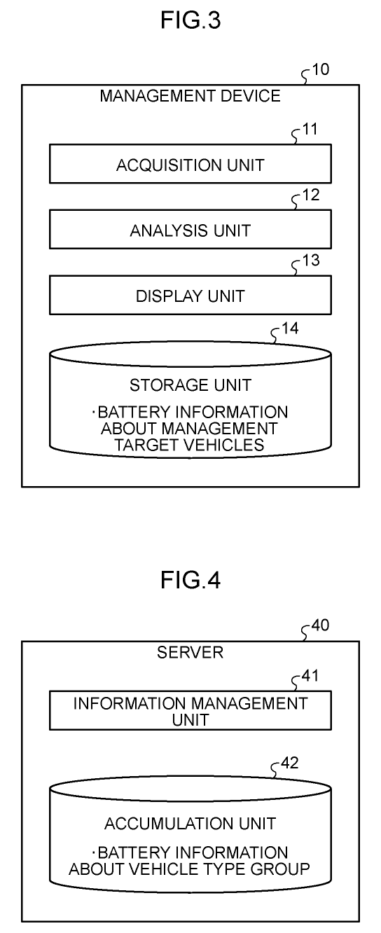

FIG. 3 is a diagram illustrating an exemplary functional configuration of the management device 10 according to an embodiment. The management device 10 executes a program loaded in the memory 52 by using the processor 51 to implement each of the functions of an acquisition unit 11, an analysis unit 12, a display unit 13, and a storage unit 14.

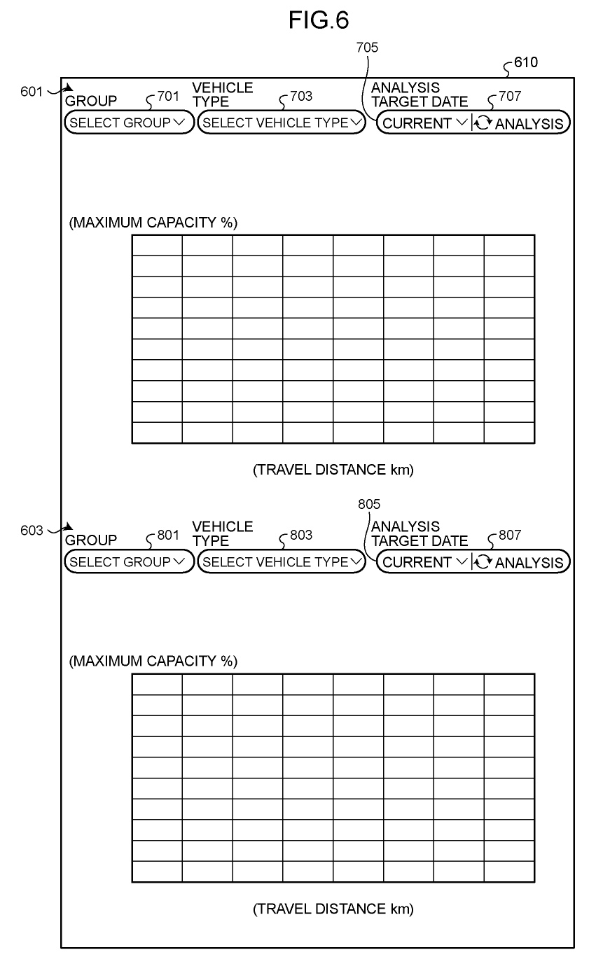

The acquisition unit 11 receives designation of the analysis target on an analysis screen, on the basis of, for example, an output from the input I/F 55 according to user operation (see FIG. 6). In addition, the acquisition unit 11 acquires the battery information about the vehicle type of the designated analysis target.

In an example, the acquisition unit 11 acquires the battery information about the vehicle type of the designated analysis target, included in the battery information about management target vehicles as the vehicles 30 managed by the company that operates the management device 10. Here, the battery information about the vehicle type of the designated analysis target is an example of first battery information.

Here, the battery information about management target vehicles may include, for example, a value of the travel distance and a value of the maximum capacity of the storage battery, for each of at least one management target vehicle 30. The battery information about management target vehicles is stored in, for example, the storage unit 14 of the management device 10, but may be stored outside the management device 10, for example, in an accumulation unit 42 of the server 40.

Note that the battery information about management target vehicles may include a value of an amount of decrease in the maximum capacity per travel distance of each of the at least one management target vehicle 30. In addition, the battery information about management target vehicles may include an average value of the values of the amounts of decrease in the maximum capacity per travel distance for each vehicle type of the at least one management target vehicle 30. This average value is an example of a first evaluation value indicating a tendency of a deterioration rate of the storage battery performance for each vehicle type. In addition, the battery information about management target vehicles may include a value of standard deviation of the first evaluation values for each vehicle type of the at least one management target vehicle 30. The value of the standard deviation is an example of a third evaluation value indicating a tendency of variation in the storage battery performance for each vehicle type.

In an example, the acquisition unit 11 acquires battery information about a vehicle type group accumulated by the company that operates the server 40. Here, the battery information about the vehicle type group is an example of second battery information.

Here, the battery information about the vehicle type group may include, for example, the first evaluation value indicating the tendency of the deterioration rate of the storage battery performance and the third evaluation value indicating the tendency of the variation in the storage battery performance, which are standardized over the entire vehicle type group registered in the support system 1. The battery information about the vehicle type group is stored in, for example, the accumulation unit 42 of the server 40, but may be partially stored in the management device 10 such as the storage unit 14 of the management device 10.

Note that the battery information about the vehicle type group may include, for example, a value of the maximum capacity of the storage battery obtained every travel distance and the value of the amount of decrease in the maximum capacity of the storage battery per travel distance, of the at least one vehicle 30 registered in the support system 1.

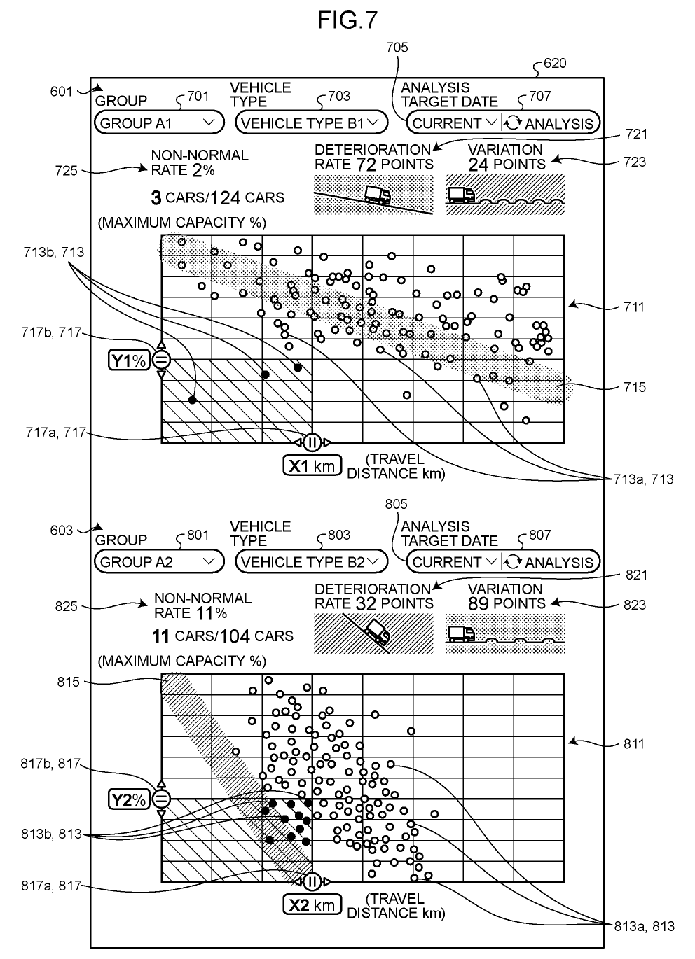

In addition, the acquisition unit 11 receives designation of a threshold of a non-normal rate on an analysis screen, on the basis of, for example, an output from the input I/F 55 according to user operation (see FIG. 7).

The analysis unit 12 analyzes the battery information about the vehicle type of the designated analysis target on the basis of the battery information acquired by the acquisition unit 11.

In an example, the analysis unit 12 calculates a value of the amount of decrease in the maximum capacity per travel distance, on the basis of the value of the travel distance and the value of the maximum capacity of the storage battery, included in the battery information about management target vehicles, for each of the at least one vehicle 30 of the vehicle type of the designated analysis target from among the management target vehicles. In addition, the analysis unit 12 calculates, as the first evaluation value indicating the tendency of the deterioration rate of the storage battery performance, the average value of the values of amounts of decrease in the maximum capacity per travel distance, for the at least one vehicle 30 of the vehicle type of the designated analysis target, from among the management target vehicles.

In an example, the analysis unit 12 compares the first evaluation value calculated from the battery information about management target vehicles with the standardized first evaluation value included in the battery information about the vehicle type group, calculating a second evaluation value indicating the degree of the deterioration rate of the storage battery performance. For example, the analysis unit 12 calculates, as the second evaluation value, a score indicating the magnitude of the first evaluation value calculated from the battery information about management target vehicles, on the basis of the standardized first evaluation value. For example, there may be an aspect in which when the first evaluation value calculated from the battery information about management target vehicles is larger than the standardized first evaluation value, the second evaluation value is set to a score of 30 points or less or a score lower than 50 points. Alternatively, there may be an aspect in which when the first evaluation value calculated from the battery information about management target vehicles is smaller than the standardized first evaluation value, the second evaluation value is set to a score of 70 points or more or a score higher than 50 points.

In an example, the analysis unit 12 calculates, as the third evaluation value indicating the tendency of the variation in the storage battery performance, the standard deviation of the values of the amounts of decrease in the maximum capacity per travel distance, for the at least one vehicle 30 of the vehicle type of the designated analysis target, from among the management target vehicles.

In an example, the analysis unit 12 compares the third evaluation value calculated from the battery information about management target vehicles with the standardized third evaluation value included in the battery information about the vehicle type group, calculating a fourth evaluation value indicating the degree of the variation in the storage battery performance. For example, the analysis unit 12 calculates, as the fourth evaluation value, a score indicating the magnitude of the third evaluation value calculated from the battery information about management target vehicles, on the basis of the standardized third evaluation value. For example, there may be an aspect in which when the third evaluation value calculated from the battery information about management target vehicles is larger than the standardized third evaluation value, the fourth evaluation value is set to a score of 30 points or less or a score lower than 50 points. Alternatively, there may be an aspect in which when the third evaluation value calculated from the battery information about management target vehicles is smaller than the standardized third evaluation value, the fourth evaluation value is set to a score of 70 points or more or a score higher than 50 points.

In an example, the analysis unit 12 calculates a fifth evaluation value indicating the degree of the non-normal rate in the storage battery performance, on the basis of the value of the travel distance of each vehicle, the value of the maximum capacity of each storage battery, and the designated threshold of the non-normal rate, for the at least one vehicle 30 of the vehicle type of the designated analysis target, from among the management target vehicles. For example, the fifth evaluation value is at least one of information indicating the number of vehicles 30 below the designated threshold of the non-normal rate with respect to the number of the at least one vehicle 30 of the vehicle type of the designated analysis target, from among the management target vehicles, and a ratio thereof.

Note that the evaluation values described above are not limited to the average value and the standard deviation, and may be calculated using other statistical values such as a median value and a variance.

The display unit 13 displays, for example, the analysis screen for designating the analysis target, on the display 54 of the management device 10. In addition, the display unit 13 displays the analysis screen for displaying a result of the evaluation based on the analysis by the analysis unit 12, on the display 54 of the management device 10. Here, the display unit 13 according to the embodiment is an example of an output unit.

The storage unit 14 is implemented by, for example, the memory 52 of the management device 10. The storage unit 14 stores the battery information about management target vehicles described above.

Note that some of the functions of the management device 10 according to the embodiment may be implemented outside the management device 10, for example, in the server device separately provided in the support system 1 and communicably connected to the management device 10 via the network N.

FIG. 4 is a diagram illustrating an exemplary functional configuration of the server 40 according to an embodiment. The server 40 executes a program loaded in the memory 52 by using the processor 51 to implement each of the functions of an information management unit 41 and the accumulation unit 42.

The information management unit 41 reads the battery information about a vehicle type meeting a request from the management device 10, from the accumulation unit 42. Furthermore, the information management unit 41 outputs the battery information read from the accumulation unit 42 to the management device 10.

The accumulation unit 42 is implemented by, for example, the memory 52 of the server 40. The accumulation unit 42 stores battery information for each vehicle type relating to at least one vehicle type registered in the support system 1 described above.

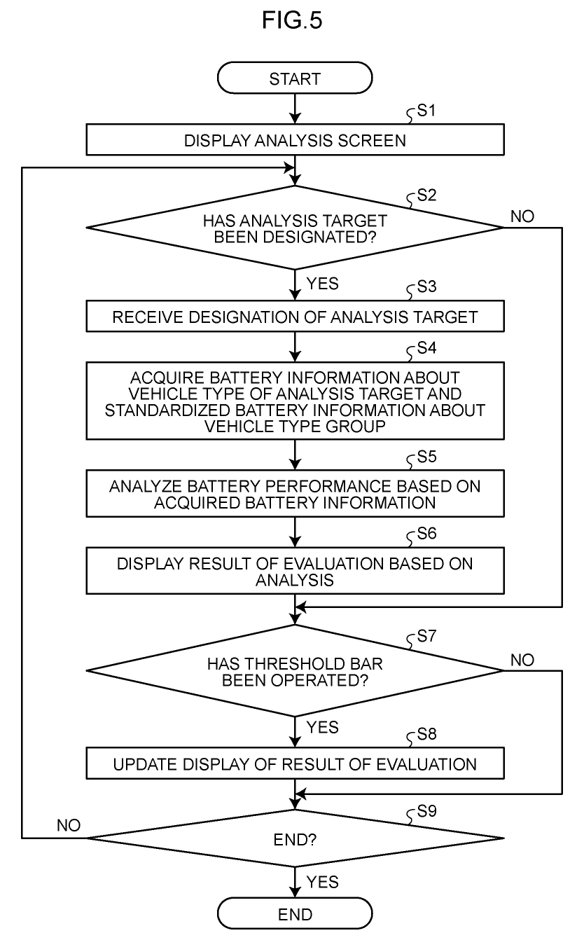

Next, a procedure of a process performed in the support system 1 configured as described above will be described. FIG. 5 is a flowchart illustrating an exemplary procedure of the support process performed by the management device 10 according to an embodiment.

First, the display unit 13 displays the analysis screen by using the display 54 (S1). FIG. 6 is a diagram illustrating an example of a display screen 610 displayed in the process of FIG. 5. The display screen 610 of FIG. 6 illustrates the analysis screen for designating the analysis target in the management device 10. In an example, the display screen 610 includes a first display area 601 and a second display area 603. Each of the first display area 601 and the second display area 603 is an area for displaying an analysis result of the storage battery performance for a designated vehicle type, that is, the result of the evaluation based on comparison with accumulated battery information about the vehicle type group.

Each of the first display area 601 and the second display area 603 is provided with an operation section for designating the analysis target. In the example of FIG. 6, the first display area 601 includes a group selection field 701, a vehicle type selection field 703, and an analysis target date selection field 705. Similarly, the second display area 603 includes a group selection field 801, a vehicle type selection field 803, and an analysis target date selection field 805.

Each of the group selection fields 701 and 801 is a display for analysis target group selection from among at least one group that is a category of each vehicle 30 managed by the company that uses the support service. Here, the group represents a management category for each vehicle 30 of the company that uses the support service, and for example, there may be a division such as a ○○ branch office or a ○○ office.

Each of the vehicle type selection fields 703 and 803 is a display for selection of the vehicle type of the analysis target from among at least one vehicle type of the at least one vehicle 30 belonging to a selected group.

Each of the analysis target date selection fields 705 and 805 is a display for selection of an analysis target period. Here, the analysis target date may be a category of time such as current, past, or all, may be a category of year, month, or week, or may be a category for designating a start point and an end point by date.

Note that in FIG. 6, the operation section for designating analysis target is not limited to the selection field for selection from the candidates registered in advance, and may be an input field for the user to directly input.

In addition, each of the first display area 601 and the second display area 603 is provided with an operation section for giving an instruction for analysis for obtaining the result of the evaluation of the designated analysis target. In the example of FIG. 6, the first display area 601 includes an operation button 707 for giving an instruction for analysis. Similarly, the second display area 603 includes an operation button 807 for giving an instruction for analysis.

Next, the acquisition unit 11 determines whether the analysis target has been designated (S2). In an example, the acquisition unit 11 determines whether each of the operation buttons 707 and 807 each giving an instruction for analysis of storage battery performance has been operated on the display screen 610, on the basis of an output from the input I/F 55 according to user operation. For example, when each of the operation buttons 707 and 807 is operated, the acquisition unit 11 determines that the analysis target has been designated.

When the analysis target is not designated (S2: No), the process of FIG. 5 proceeds to the processing of S7.

Meanwhile, when the analysis target is designated (S2: Yes), the acquisition unit 11 receives designation of the analysis target (S3). In an example, the acquisition unit 11 receives an operation result in the operation section for designating the analysis target on the display screen 610 as the analysis screen, on the basis of, for example, an output from the input I/F 55 according to user operation. For example, when the operation buttons 707 and 807 of the first display area 601 are operated, the acquisition unit 11 receives designation of the analysis target by the selection fields 701, 703, and 705. Similarly, when the operation button 807 of the second display area 603 is operated, the acquisition unit 11 receives designation of the analysis target by the selection fields 801, 803, and 805.

In addition, the acquisition unit 11 acquires the battery information about the vehicle type of the designated analysis target and standardized battery information about the vehicle type group (S4). In an example, the acquisition unit 11 acquires, from the storage unit 14, battery information about the management target vehicles 30 according to the received designation of the analysis target. In addition, the acquisition unit 11 requests the battery information about the vehicle type group, from the server 40. At this time, the information management unit 41 of the server 40 reads the battery information about the vehicle type group from the accumulation unit 42 in response to the request from the management device 10, and outputs the battery information to the management device 10. Then, the acquisition unit 11 of the management device 10 acquires the battery information about the vehicle type group from the server 40.

The analysis unit 12 analyzes battery performance on the basis of the acquired battery information (S5). In an example, the analysis unit 12 calculates a storage battery performance evaluation value by analysis using the battery information about the vehicle type of the designated analysis target and the standardized battery information about the vehicle type group. The storage battery performance evaluation value includes at least one of the first evaluation value indicating the tendency of the deterioration rate, the second evaluation value indicating the degree of the deterioration rate, the third evaluation value indicating the tendency of the variation, the fourth evaluation value indicating the degree of the variation, and the fifth evaluation value indicating the degree of the non-normal rate.

The display unit 13 displays the result of the evaluation about the storage battery performance for each vehicle type based on the analysis by the analysis unit 12, on the analysis screen (S6). FIG. 7 is a view illustrating an example of a display screen 620 displayed in the process of FIG. 5. The display screen 620 of FIG. 7 illustrates the analysis screen displaying the result of the evaluation of the storage battery performance for each vehicle type based on the analysis. In an example, the display screen 620 of FIG. 7 includes the first display area 601 and the second display area 603, as in the display screen 610 of FIG. 6. The display screen 620 of FIG. 7 illustrates the analysis screen where results 711 and 811 of the evaluation are displayed on the display screen 610 of FIG. 6.

The first display area 601 of the display screen 620 of FIG. 7 displays the result 711 of the evaluation for "group A1", "vehicle type B1", and "current" that are designated by the selection fields 701, 703, and 705. Similarly, the second display area 603 displays the result 811 of the evaluation for "group A2", "vehicle type B2", and "current" that are designated by the selection fields 801, 803, and 805.

In addition, on the display screen 620 of FIG. 7, display of the results 711 and 811 of the evaluation includes display of scatter diagrams showing the storage battery performance by plots 713 and 813, for each of at least one management target vehicle 30 as the designated analysis target, with the horizontal axis as the value of the travel distance and with the vertical axis the value of the maximum capacity of the storage battery. According to the display of the scatter diagram, the user can grasp the storage battery performance of the vehicle 30 as the analysis target in a bird's-eye view, or compare the storage battery performance between the vehicle types as comparison targets.

In addition, on the display screen 620 of FIG. 7, the first evaluation value indicating the tendency of the deterioration rate of the storage battery performance is represented on the scatter diagram by display 715 and 815 of linear shapes each indicating the magnitude of the value as an inclination. In the example of FIG. 7, the display 715 and 815 indicate that the larger the first evaluation value, the larger the inclination, and the deterioration rate increases. According to the display 715 and 815 of the first evaluation value, the user can intuitively grasp the magnitude of the deterioration rate and compare the deterioration rate between vehicle types as the comparison targets.

In addition, on the display screen 620 of FIG. 7, the second evaluation value indicating the degree of the deterioration rate of the storage battery performance is represented by display 721 and 821 indicating the values of the second evaluation value by numerical values and icons. In the example of FIG. 7, the display 721 and 821 indicate that the larger the second evaluation value, the lower the score, and that the deterioration rate is increased. Note that each of the display 721 and 821 may use one of the numerical value and the icon. According to the display of the scores of the second evaluation value in the display 721 and 821, the user can quantitatively grasp the magnitude of the deterioration rate and compare the magnitude between the vehicle types as the comparison targets. In addition, according to the display of the icon, the user can qualitatively grasp the magnitude of the deterioration rate and compare the deterioration rate between the vehicle types as the comparison targets.

Note that on the display screen 620 of FIG. 7, the third evaluation value indicating the tendency of the variation in the storage battery performance may be represented as, for example, the width (thickness) of the display 715 and 815 of the first evaluation value. For example, the display 715 and 815 may be made larger in thickness as the third evaluation value is larger. According to this configuration, the user can intuitively grasp the magnitude of the variation and compare the magnitude of the variation between the vehicle types as the comparison targets.

In addition, on the display screen 620 of FIG. 7, the fourth evaluation value indicating the degree of the variation in the storage battery performance is represented by display 723 and 823 indicating the value of the fourth evaluation value by numerical values and icons. In the example of FIG. 7, the display 723 and 823 indicate that the larger the fourth evaluation value, the lower the score, and that the variation is increased. Note that each of the display 723 and 823 may use one of the numerical value and the icon. According to the display of the scores of the fourth evaluation value in the display 723 and 823, the user can quantitatively grasp the magnitude of the variation and compare the magnitude of the variation between the vehicle types as the comparison targets. In addition, according to the display of the icon, the user can qualitatively grasp the magnitude of the variation and compare the magnitude of the variation between the vehicle types as the comparison targets.

In addition, on the display screen 620 of FIG. 7, display of the scatter diagrams indicating the results 711 and 811 of the evaluation includes display of threshold bars 717 and 817 that are operation bars for designating the threshold of the non-normal rate. Display of the threshold bar 717 includes display of threshold bars 717a and 717b. The threshold bar 717a is an operation icon for designating the threshold of the travel distance on the horizontal axis, for the scatter diagram indicating the result 711 of the evaluation displayed in the first display area 601. The threshold bar 717b is an operation icon for designating the threshold of the maximum capacity on the vertical axis, for the scatter diagram indicating the result 711 of the evaluation displayed in the first display area 601. Display of the threshold bar 817 includes display of threshold bars 817a and 817b. The threshold bar 817a is an operation icon for designating the threshold of the travel distance on the horizontal axis, for the scatter diagram indicating the result 811 of the evaluation displayed in the second display area 603. The threshold bar 817b is an operation icon for designating the threshold of the maximum capacity on the vertical axis, for the scatter diagram indicating the result 811 of the evaluation displayed in the second display area 603. Note that display of the threshold bars 717 and 817 may designate at least one of the threshold of the travel distance and the threshold of the maximum capacity. In other words, for the threshold of the non-normal rate, the threshold about at least one of the travel distance and the maximum capacity may be designated.

In addition, on the display screen 620 of FIG. 7, the plots 713 and 813 in the scatter diagrams may be represented so that plots 713a and 813a that satisfy the threshold of the non-normal rate designated by using the threshold bars 717 and 817 and plots 713b and 813b that do not satisfy the threshold can be visually distinguished. Furthermore, on the display screen 620 of FIG. 7, a region in the scatter diagram that does not satisfy the threshold of the non-normal rate designated by using the threshold bars 717 and 817 may be represented so as to be visually distinguished.

In addition, on the display screen 620 of FIG. 7, the fifth evaluation value indicating the degree of the non-normal rate in the storage battery performance is represented by display 725 and 825 indicating the number of vehicles 30 below the designated threshold of the non-normal rate with respect to the number of vehicles 30 of the vehicle type of the analysis target from among the management target vehicles, and a ratio thereof. Note that the display 725 and 825 may be one of the number of vehicles 30 below the threshold and the ratio thereof. According to the display 725 and 825 of the fifth evaluation value, the user can quantitatively grasp the number and the ratio of the vehicles 30 below the designated threshold of the non-normal rate, and compare the number and the ratio thereof between the vehicle types as the comparison targets. Note that the fifth evaluation value may be defined using a normal rate instead of the non-normal rate.

Here, returning back to FIG. 5 again, the support process executed by the management device 10 according to the embodiment will be described.

The acquisition unit 11 determines whether the threshold bar 817 has been operated (S7). In an example, the acquisition unit 11 determines whether the threshold bars 717 and 817 each designating the threshold of the non-normal rate have been operated on the display screen 620, on the basis of an output from the input I/F 55 according to user operation.

When the threshold bar 817 is not operated (S7: No), the process of FIG. 5 proceeds to processing of S9.

Meanwhile, when the threshold bar 817 is operated (S7: Yes), the acquisition unit 11 receives the change of the threshold of the non-normal rate, and updates display of the result of the evaluation on the analysis screen according to the changed threshold of the non-normal rate (S8).

Thereafter, the acquisition unit 11 determines whether to finish the support process of FIG. 5 for evaluation of the storage battery performance, on the basis of, for example, an output from the input I/F 55 according to user operation (S9). When the process is not finished (S9: No), the process of FIG. 5 returns to the processing of S2. When the process is finished (S9: Yes), the display unit 13 finishes display of the analysis screen on the display 54. Thereafter, the process of FIG. 5 is finished.

Note that in the support process according to the present embodiment, the first display area 601 and the second display area 603 are configured to be capable of independently displaying the results of the evaluation of the storage battery performance. Therefore, in the first display area 601 and the second display area 603, results of the evaluation in which any one of the designated analysis targets is different are displayed in a comparable manner, for comparison, but the results of the evaluation for the same analysis target may be displayed. For example, when the results of the evaluation for the same analysis target are displayed, the non-normal rate obtained when different thresholds are set can also be displayed in a comparable manner.

In addition, when the result of the evaluation is calculated and displayed in one of the first display area 601 and the second display area 603, and instruction for analysis is given in such a state, for an analysis target designated or changed in the other display area, a display scale of the other scatter diagram may be changed according to the display of a new result of the evaluation.

Note that the analysis screen is not limited to the two display areas of the first display area 601 and the second display area 603, and may have three or more display areas. In addition, the first display area 601 and the second display area 603 are not limited to display arrangement on the upper and lower sides, and may be displayed side by side on the left and right sides. In addition, the first display area 601 and the second display area 603 are not limited to display arrangement side by side, and may be configured as one display area, for example, by being displayed in an overlapping manner. For example, the analysis screen may be a display screen in which one scatter diagram displays two or more vehicle types as the comparison targets. For example, the analysis screen may collectively display the evaluation values of two or more vehicle types as the comparison targets in one display area. Alternatively, the analysis screen may display statistical values such as a value of difference or an average value in evaluation for two or more vehicle types as the comparison targets instead of or in addition to each evaluation value.

Note that on the analysis screen, the scatter diagram may have the maximum capacity on the horizontal axis and the travel distance on the vertical axis. Furthermore, in place of the travel distance, various parameters may be used that affect deterioration of the storage battery, such as the number of years elapsed from manufacture, power consumption, travel time, charge amount, charge time, and charge and discharge cycles.

Furthermore, in the analysis screen, the scatter diagram is not an essential configuration and may not be displayed. For example, the analysis screen may be a display screen for displaying only scores and icons indicating the evaluation values. Alternatively, the analysis screen may be a display screen for displaying only the scatter diagram and the first evaluation value. In this configuration, the acquisition unit 11 only needs to acquire the first battery information about the management target vehicles 30, and does not need to acquire the second battery information being the battery information about the vehicle type group, from the server 40. Furthermore, the analysis unit 12 preferably calculates the first evaluation value on the basis of only the first battery information about the management target vehicles 30, that is, without using the second battery information.

Note that the analysis target date selection fields 705 and 805 may be configured to be able to designate a category such as the future and a future date. Similarly, for display of the results 711 and 811 of the evaluation, a scatter diagram or evaluation values that indicate future storage battery performance may be calculated and displayed. In other words, the results 711 and 811 of the evaluation can display not only a current result but also evaluation values such as a scatter diagram, a score, and an icon that indicate the future such as one year later or five years later by using, for example, a deterioration prediction technique. According to this configuration, it is possible to provide storage battery performance evaluation information as the evaluation criteria for considering additional purchase or update of the vehicles 30 in the future in advance to support the operation management business.

Note that the vehicle type selection fields 703 and 803 may be able to select, as the vehicle type of the analysis target, a vehicle type not owned by the company that manages the operation of the electrically driven vehicles. Alternatively, an input field in which a vehicle type that is not owned can be input as a vehicle type of the analysis target may be displayed. Similarly, as display of the results 711 and 811 of the evaluation, a scatter diagram and an evaluation value indicating a result of the evaluation for a vehicle type not owned by the company that manages the operation of the electrically driven vehicles may be calculated and displayed. For example, the storage unit 14 of the management device 10 or the accumulation unit 42 of the server 40 may store a correction amount of the battery information set in advance on the basis of a performance difference in the storage battery performance between the vehicle types. Furthermore, for example, the analysis unit 12 may correct the battery information about the vehicles 30 of the vehicle type owned by the company that manages the operation of the electrically driven vehicles by using the correction amount to calculate the scatter diagram and evaluation values for the vehicle type not owned by the company. According to this configuration, it is possible to provide the storage battery performance evaluation information as the evaluation criteria for considering introduction of a vehicle type not owned to support the operation management business in addition to considering additional purchase of the vehicle type owned. In addition, according to the aspect of correcting the battery information about the vehicles 30 owned, it is possible to simulate a result of the evaluation of the vehicle type not owned when the vehicle is used in the same manner as the vehicles 30 owned.

Note that the battery information about the vehicles 30 owned by the company may be automatically acquired, for example, upon charging and stored in the management device 10, may be received in response to an input by the company by using the HMI 53, or may be acquired on the basis of data obtained by scanning a paper medium such as a maintenance record. In an example, a controller for the storage battery mounted on each vehicle 30 may be communicably connected to an in-vehicle network including, for example, a controller area network (CAN), Ethernet (registered trademark), or the like. Furthermore, for example, a computer such as an electronic control unit (ECU) or an on board unit (OBU) provided in the vehicle 30 may be communicably connected to the controller of the storage battery mounted on the vehicle 30, via the in-vehicle network. Furthermore, for example, the computer may be communicably connected to the management device 10 or the server 40 via the network N. Furthermore, for example, the computer may output the battery information about the storage battery mounted on the vehicle 30 to the management device 10 or the server 40 via the network N, or through direct connection thereto.

Note that the management device 10 according to the above-described embodiment may not include the display 54. In other words, the management device 10 may be configured as a device that outputs, to the outside, the results 711 and 811 of the evaluation and display information for displaying the analysis screen including the result of the evaluation. In this configuration, the processor 51 may be configured to implement an output unit that outputs the display information, for example by using the communication I/F 56, instead of the display unit 13.

As described above, in the support system 1 according to the embodiment, the management device 10 is configured to acquire the battery information about the storage battery mounted on the at least one vehicle 30, for any vehicle type managed by the company that conducts the operation management business, and acquire the standardized battery information based on big data of the battery information about the vehicle type group, accumulated in the server 40. In addition, the management device 10 is configured to calculate the evaluation value about the battery performance of the storage battery by analysis of comparing the acquired battery information, and output the display information for displaying the result of the evaluation.

According to this configuration, it is possible to provide the storage battery performance information that supports the operation management business managing the electrically driven vehicles with storage batteries mounted. For example, according to the above configuration, it is possible to provide the storage battery performance information that serves as the evaluation criteria for additional introduction of an electrically driven vehicle by the company that manages the plurality of vehicles of the plurality of vehicle types, such as the transport company, the logistics company, or the rental car company. For example, according to the above configuration, it is possible to provide the information according to the operation form for each company as the storage battery performance information. For example, according to the above configuration, it is possible to provide the user interface system that allows the company that owns electrically driven vehicles with storage batteries mounted to readily grasp a vehicle type having good storage battery performance.

Note that in the above embodiments, "determine whether something is A" may be to determine that something is A, to determine that something is not A, or to determine whether something is A or not.

Programs executed on the devices of the support system 1 according to an embodiment described above are provided by being recorded in the form of installable or executable file, on a computer-readable storage medium, such as CD-ROM, FD, CD-R, and DVD.

The programs executed on the devices of the support system 1 according to an embodiment described above may be configured to be stored on a computer connected to a network such as the Internet and provided by being downloaded via the network. In addition, the programs executed on the devices of the support system 1 according to an embodiment described above may be provided or distributed via a network such as the Internet.

In addition, the programs executed on the devices of the support system 1 according to an embodiment described above may be provided by being incorporated in ROM and the like in advance.

In addition, the programs executed on the devices of the support system 1 according to an embodiment described above have a module configuration including the above-described functional units, and as actual hardware, the processor 51 such as a CPU reads and executes a program from the memory 52 such as ROM and HDD, whereby each of the functional units is loaded onto the RAM of the memory 52, and each of the functional units is generated on the RAM of the memory 52.

According to at least one embodiment described above, it is possible to provide the storage battery performance evaluation information that supports the operation management business managing the electrically driven vehicles with storage batteries mounted.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

### Supplementary notes

The following techniques are disclosed from the above descriptions of the embodiments.

(1)

An operation management support method including:

acquiring first battery information about a storage battery mounted on at least one vehicle of a first vehicle type as a management target and second battery information about storage batteries of a vehicle type group including at least the first vehicle type;

comparing the first battery information with the second battery information to perform analyzation of storage battery performance of the first vehicle type; and

outputting display information for displaying a result of evaluation of the storage battery performance of the first vehicle type based on the analysis.

(2)

The operation management support method according to (1), wherein

the first battery information includes, for each of the at least one vehicle, a value of a parameter affecting deterioration of the storage battery and a value of a maximum capacity of the storage battery,

the analyzation includes calculating a first evaluation value indicating a tendency of a deterioration rate of the storage battery performance based on the value of the parameter and the value of the maximum capacity of the storage battery, and

the display information includes information for displaying the first evaluation value in a linear shape having an inclination corresponding to a magnitude of the first evaluation value in a graph having two orthogonal axes representing the parameter, and the maximum capacity of the storage battery.

(3)

The operation management support method according to (2), wherein

the second battery information includes the first evaluation value standardized over the entire vehicle type group,

the analyzation includes comparing the first evaluation value based on the first battery information with the first evaluation value standardized over the entire vehicle type group to calculate a second evaluation value indicating a degree of the deterioration rate of the storage battery performance, and

the display information includes information for displaying the second evaluation value by at least one of a numerical value and an icon.

(4)

The operation management support method according to (2) or (3), wherein

the analyzation includes calculating standard deviation of values of amounts of decrease in the maximum capacity per the parameter as a third evaluation value indicating a tendency of variation in the storage battery performance, and

the display information includes information for displaying the linear shape with a thickness corresponding to a magnitude of the third evaluation value.

(5)

The operation management support method according to (4), wherein

the second battery information includes the third evaluation value standardized over the entire vehicle type group,

the analyzation includes comparing the third evaluation value based on the first battery information with the third evaluation value standardized over the entire vehicle type group to calculate a fourth evaluation value indicating a degree of variation in the storage battery performance, and

the display information includes information for displaying the fourth evaluation value by at least one of a numerical value and an icon.

(6)

The operation management support method according to any one of (1) to (5), wherein

the first battery information includes, for each of the at least one vehicle, a value of a parameter affecting deterioration of the storage battery and a value of a maximum capacity of the storage battery,

the operation management support method further includes receiving designation of a threshold of a non-normal rate relating to at least one of the parameter and the maximum capacity of the storage battery,

the analyzation includes calculating a fifth evaluation value indicating a degree of the non-normal rate in the storage battery performance, based on the value of the parameter, the value of the maximum capacity of the storage battery, and the designated threshold of the non-normal rate, and

the display information includes information for displaying the fifth evaluation value by at least one of a number and a ratio of vehicles below the designated threshold of the non-normal rate from among the at least one vehicle.

(7)

The operation management support method according to any of (1) to (6), wherein

the acquiring includes acquiring the first battery information about a storage battery mounted on at least one vehicle of a second vehicle type different from the first vehicle type as the management target,

the analyzation includes comparing the first battery information with the second battery information to perform analyzation relating to storage battery performance of the second vehicle type, and

the outputting includes outputting display information for displaying results of evaluation of the storage battery performance of the first vehicle type and the second vehicle type, based on the analysis in a comparable manner.

(8)

An operation management support apparatus including:

an acquisition unit that acquires first battery information about a storage battery mounted on at least one vehicle of a first vehicle type as a management target and second battery information about storage batteries of a vehicle type group including at least the first vehicle type;

an analysis unit that compares the first battery information with the second battery information to perform analyzation of storage battery performance of the first vehicle type; and

an output unit that outputs display information for displaying a result of evaluation of the storage battery performance of the first vehicle type based on the analysis.

(9)

The operation management support apparatus according to (8), wherein

the first battery information includes, for each of the at least one vehicle, a value of a parameter affecting deterioration of the storage battery and a value of a maximum capacity of the storage battery,

the analysis unit calculates a first evaluation value indicating a tendency of a deterioration rate of the storage battery performance based on the value of the parameter and the value of the maximum capacity of the storage battery, and

the output unit outputs the display information for displaying the first evaluation value in a linear shape having an inclination corresponding to a magnitude of the first evaluation value in a graph having two orthogonal axes representing the parameter, and the maximum capacity of the storage battery.

(10)

The operation management support apparatus according to (9), wherein

the second battery information includes the first evaluation value standardized over the entire vehicle type group,

the analysis unit compares the first evaluation value based on the first battery information with the first evaluation value standardized over the entire vehicle type group to calculate a second evaluation value indicating a degree of the deterioration rate of the storage battery performance, and

the output unit outputs the display information for displaying the second evaluation value by at least one of a numerical value and an icon.

(11)

The operation management support apparatus according to (9) or (10), wherein

the analysis unit calculates standard deviation of a values of amounts of decrease in the maximum capacity per the parameter as a third evaluation value indicating a tendency of variation in the storage battery performance, and

the output unit outputs the display information for displaying the linear shape with a thickness corresponding to a magnitude of the third evaluation value.

(12)

The operation management support apparatus according to (11), wherein

the second battery information includes the third evaluation value standardized over the entire vehicle type group,

the analysis unit compares the third evaluation value based on the first battery information with the third evaluation value standardized over the entire vehicle type group to calculate a fourth evaluation value indicating a degree of the variation in the storage battery performance, and

the output unit outputs the display information for displaying the fourth evaluation value by at least one of a numerical value and an icon.

(13)

The operation management support apparatus according to any one of (8) to (12), wherein

the first battery information includes, for each of the at least one vehicle, a value of a parameter affecting deterioration of the storage battery and a value of a maximum capacity of the storage battery,

the acquisition unit further acquires designation of a threshold of a non-normal rate relating to at least one of the parameter and the maximum capacity of the storage battery,

the analysis unit calculates a fifth evaluation value indicating a degree of the non-normal rate in the storage battery performance, based on the value of the parameter, the value of the maximum capacity of the storage battery, and the designated threshold of the non-normal rate, and

the output unit outputs the display information for displaying the fifth evaluation value by at least one of the number and a ratio of vehicles below the designated threshold of the non-normal rate from among the at least one vehicle.

(14)

The operation management support apparatus according to any of (8) to (13), wherein

the acquisition unit further acquires the first battery information about a storage battery mounted on at least one vehicle of a second vehicle type different from the first vehicle type as the management target,

the analysis unit compares the first battery information with the second battery information to perform analyzation of storage battery performance of the second vehicle type, and

the output unit outputs the display information for displaying results of the evaluation of the storage battery performance of the first vehicle type and the second vehicle type, based on the analysis in a comparable manner.

(15)

A program for causing a computer to execute the operation management support method according to any of (1) to (7) described above.

(16)

A recording medium (computer program product) including the program according to (15) described above, the program being executed by a computer.

What is claimed is:

1. An operation management support method comprising:
acquiring first battery information about a storage battery mounted on at least one vehicle of a first vehicle type as a management target and second battery information about storage batteries of a vehicle type group including at least the first vehicle type;
comparing the first battery information with the second battery information to perform analyzation of storage battery performance of the first vehicle type; and
outputting display information for displaying a result of evaluation of the storage battery performance of the first vehicle type based on the analysis.

2. The operation management support method according to claim 1, wherein
the first battery information includes, for each of the at least one vehicle, a value of a parameter affecting deterioration of the storage battery and a value of a maximum capacity of the storage battery,
the analyzation includes calculating a first evaluation value indicating a tendency of a deterioration rate of the storage battery performance based on the value of the parameter and the value of the maximum capacity of the storage battery, and
the display information includes information for displaying the first evaluation value in a linear shape having an inclination corresponding to a magnitude of the first evaluation value in a graph having two orthogonal axes representing the parameter, and the maximum capacity of the storage battery.

3. The operation management support method according to claim 2, wherein
the second battery information includes the first evaluation value standardized over the entire vehicle type group,
the analyzation includes comparing the first evaluation value based on the first battery information with the first evaluation value standardized over the entire vehicle type group to calculate a second evaluation value indicating a degree of the deterioration rate of the storage battery performance, and
the display information includes information for displaying the second evaluation value by at least one of a numerical value and an icon.

4. The operation management support method according to claim 2, wherein
the analyzation includes calculating standard deviation of values of amounts of decrease in the maximum capacity per the parameter as a third evaluation value indicating a tendency of variation in the storage battery performance, and
the display information includes information for displaying the linear shape with a thickness corresponding to a magnitude of the third evaluation value.

5. The operation management support method according to claim 4, wherein
the second battery information includes the third evaluation value standardized over the entire vehicle type group,
the analyzation includes comparing the third evaluation value based on the first battery information with the third evaluation value standardized over the entire vehicle type group to calculate a fourth evaluation value indicating a degree of variation in the storage battery performance, and
the display information includes information for displaying the fourth evaluation value by at least one of a numerical value and an icon.

6. The operation management support method according to claim 1, wherein
the first battery information includes, for each of the at least one vehicle, a value of a parameter affecting deterioration of the storage battery and a value of a maximum capacity of the storage battery,
the operation management support method further comprises receiving designation of a threshold of a non-normal rate relating to at least one of the parameter and the maximum capacity of the storage battery,
the analyzation includes calculating a fifth evaluation value indicating a degree of the non-normal rate in the storage battery performance, based on the value of the parameter, the value of the maximum capacity of the storage battery, and the designated threshold of the non-normal rate, and
the display information includes information for displaying the fifth evaluation value by at least one of a number and a ratio of vehicles below the designated threshold of the non-normal rate from among the at least one vehicle.

7. The operation management support method according to claim 1, wherein
the acquiring includes acquiring the first battery information about a storage battery mounted on at least one vehicle of a second vehicle type different from the first vehicle type as the management target,
the analyzation includes comparing the first battery information with the second battery information to perform analyzation relating to storage battery performance of the second vehicle type, and
the outputting includes outputting display information for displaying results of evaluation of the storage battery performance of the first vehicle type and the second vehicle type, based on the analysis in a comparable manner.

8. An operation management support apparatus comprising:
a memory; and
a hardware processor coupled to the memory and configured to:
acquire first battery information about a storage battery mounted on at least one vehicle of a first vehicle type as a management target and second battery information about storage batteries of a vehicle type group including at least the first vehicle type;
compare the first battery information with the second battery information to perform analyzation of storage battery performance of the first vehicle type; and
output display information for displaying a result of evaluation of the storage battery performance of the first vehicle type based on the analysis.

9. The operation management support apparatus according to claim 8, wherein
the first battery information includes, for each of the at least one vehicle, a value of a parameter affecting deterioration of the storage battery and a value of a maximum capacity of the storage battery, and
the hardware processor is configured to:
calculate a first evaluation value indicating a tendency of a deterioration rate of the storage battery performance based on the value of the parameter and the value of the maximum capacity of the storage battery; and
output the display information for displaying the first evaluation value in a linear shape having an inclination corresponding to a magnitude of the first evaluation value in a graph having two orthogonal axes representing the parameter, and the maximum capacity of the storage battery.

10. The operation management support apparatus according to claim 9, wherein
the second battery information includes the first evaluation value standardized over the entire vehicle type group, and
the hardware processor is configured to:
compare the first evaluation value based on the first battery information with the first evaluation value standardized over the entire vehicle type group to calculate a second evaluation value indicating a degree of the deterioration rate of the storage battery performance; and
output the display information for displaying the second evaluation value by at least one of a numerical value and an icon.

11. The operation management support apparatus according to claim 9, wherein
the hardware processor is configured to:
calculate standard deviation of a values of amounts of decrease in the maximum capacity per the parameter as a third evaluation value indicating a tendency of variation in the storage battery performance; and
output the display information for displaying the linear shape with a thickness corresponding to a magnitude of the third evaluation value.

12. The operation management support apparatus according to claim 11, wherein
the second battery information includes the third evaluation value standardized over the entire vehicle type group,
the hardware processor is configured to:
compare the third evaluation value based on the first battery information with the third evaluation value standardized over the entire vehicle type group to calculate a fourth evaluation value indicating a degree of the variation in the storage battery performance; and
output the display information for displaying the fourth evaluation value by at least one of a numerical value and an icon.

13. The operation management support apparatus according to claim 8, wherein
the first battery information includes, for each of the at least one vehicle, a value of a parameter affecting deterioration of the storage battery and a value of a maximum capacity of the storage battery,
the hardware processor is configured to:
further acquire designation of a threshold of a non-normal rate relating to at least one of the parameter and the maximum capacity of the storage battery;
calculate a fifth evaluation value indicating a degree of the non-normal rate in the storage battery performance, based on the value of the parameter, the value of the maximum capacity of the storage battery, and the designated threshold of the non-normal rate; and
output the display information for displaying the fifth evaluation value by at least one of the number and a ratio of vehicles below the designated threshold of the non-normal rate from among the at least one vehicle.

14. The operation management support apparatus according to claim 8, wherein
the hardware processor is configured to:
further acquire the first battery information about a storage battery mounted on at least one vehicle of a second vehicle type different from the first vehicle type as the management target;
compare the first battery information with the second battery information to perform analyzation of storage battery performance of the second vehicle type; and
output the display information for displaying results of the evaluation of the storage battery performance of the first vehicle type and the second vehicle type, based on the analysis in a comparable manner.
